(19) United States
(12) Patent Application Publication
(10) Pub. No.: US 2003/0186529 A1
(43) Pub. Date: Oct. 2, 2003

(54) Method of manufacturing semiconductor device having opening

(75) Inventors: Takashi Goto, Ushiku-shi (JP); Norihiro Ikeda, Ibi-gun (JP); Yoshikazu Yamaoka, Ogaki-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/395,066

(22) Filed: Mar. 25, 2003

(30) Foreign Application Priority Data
Mar. 27, 2002 (JP) JP2002-87610
Mar. 13, 2003 (JP) JP2003-67690

(51) Int. Cl. H01L 21/4763

(52) U.S. Cl. 438/622; 438/636; 438/638

(57) ABSTRACT

A method of manufacturing a semiconductor device capable of preventing reduction of reliability when employing an anti-reflection coating for forming two stages of openings in an interlayer dielectric film is obtained. This method of manufacturing a semiconductor device comprises steps of forming a first resist pattern on a prescribed region of the anti-reflection coating, forming a first opening in the interlayer dielectric film through a mask of the first resist pattern, removing the first resist pattern while leaving the anti-reflection coating and thereafter forming a second resist pattern on a prescribed region of the anti-reflection coating and forming a second opening having a larger opening area than the first opening at least on an upper portion of the first opening through a mask of the second resist pattern.

### BACKGROUND OF THE INVENTION

1. Field of the Invention

The present invention relates to a method of manufacturing a semiconductor device, and more particularly, it relates to a method of manufacturing a semiconductor device having an opening.

2. Description of the Background Art

In recent years, a dual damascene process has been employed in formation of a multilevel interconnection of a semiconductor device for reducing the number of manufacturing steps for the semiconductor device. In such a dual damascene process, a via hole and a wiring trench are formed in-an interlayer dielectric film and thereafter filled up with a metal thereby simultaneously forming a damascene wire defining an upper wiring layer and a plug for attaining contact between the damascene wire and a lower wiring layer. A process of forming the via hole and the wiring trench in this dual damascene process includes a method of forming the via hole in the interlayer dielectric film for attaining contact with the lower wiring layer and thereafter further opening an upper portion of the via hole thereby forming the wiring trench for the damascene wire.

In general, the aforementioned via hole and the wiring trench are formed through lithography. If the via hole and the wiring trench are formed through lithography, however, light incident upon a photosensitive resist film disadvantageously interferes with light reflected from the interlayer dielectric film forming a pattern when the resist film is exposed with light. As a result of such interference, the quantity of light for exposing the resist film is dispersed due to small dispersion in the thickness of the resist film or the like. Such dispersion in the quantity of light for exposing the resist film results in reduction of accuracy in pattern formation of the via hole and the wiring trench, to disadvantageously cause dispersion in the dimensions of the plug and the damascene wire formed on a semiconductor substrate.

In general, therefore, an anti-reflection coating consisting of an organic material is provided between the interlayer dielectric film and the resist film, in order to relax the interference between the light incident upon the resist film and the light reflected from the interlayer dielectric film. For example, Japanese Patent Laying-Open No. 2002-373936 discloses such an anti-reflection coating. This anti-reflection coating suppresses reflection of the exposure light, thereby relaxing the interference. Thus, a semiconductor device including a plug and a damascene wire having uniform dimensions can be manufactured.

When the wiring trench is formed, however, the anti-reflection coating of an organic material formed by application partially enters the via hole. The part of the anti-reflection coating entering the via hole cannot be removed by development in a lithographic step. The part of the anti-reflection coating remaining in the via hole disadvantageously hinders formation of the plug or the damascene wire. This problem is now described in detail with reference to FIGS. 33 to 41.

First, a MOS transistor and a wiring structure connected to the MOS transistor are formed on the surface of a semiconductor substrate 101, as shown in FIG. 33. The MOS transistor includes a pair of source/drain regions 102 formed at a prescribed interval to hold a channel region therebetween and a gate electrode 104 formed on the channel region through a gate insulator film 103. The wiring structure connected to the MOS transistor includes tungsten plugs 106 formed to fill up via holes 105a of an interlayer dielectric film 105, diffusion preventing films 107 of TaN formed along the surfaces of wiring trenches 105b of the interlayer dielectric film 105 and wires 108 of Cu or the like formed in regions enclosed with the diffusion preventing films 107.

Then, a diffusion preventing film 109 consisting of SiCN is formed to cover the overall surfaces of the aforementioned MOS transistor and the wiring structure connected to the MOS transistor.

Another interlayer dielectric film 110 is formed to cover the diffusion preventing film 109. As shown in FIG. 34, a first anti-reflection coating 120a consisting of an organic material and a first resist film 121 also consisting of an organic material are successively formed on the interlayer dielectric film 110 by application. As shown in FIG. 35, a resist pattern 121p for defining a via hole 111 is formed through treatments such as exposure, development, rinsing (cleaning) and baking on the first resist film 121. The resist pattern 121p is employed as a mask for etching the first anti-reflection coating 120a and the interlayer dielectric film 110 as well as the diffusion preventing film 109, thereby forming the via hole 111. Thereafter the resist pattern 121p and the first anti-reflection coating 120a are removed thereby obtaining a structure shown in FIG. 36.

In general, both of the first anti-reflection coating 120a and the first resist film 121 are made of organic materials, and hence the first anti-reflection coating 120a is also removed in ashing for removing the resist pattern 121p consisting of the first resist film 121.

As shown in FIG. 37, a second anti-reflection coating 120b consisting of an organic material and a second resist film 130 also consisting of an organic material are formed on the interlayer dielectric film 110 by application. As shown in FIG. 38, a resist pattern 130p for defining a damascene wire is formed through treatments such as exposure, development, rinsing and baking on the second resist film 130. As shown in FIG. 39, the resist pattern 130p is employed as a mask for etching the second anti-reflection coating 120b and the interlayer dielectric film 100, thereby forming a wiring trench 112.

At this time, however, the second anti-reflection coating 120b remains in the via hole 111, as show in FIG. 39. Even if the remaining second anti-reflection coating 120b is removed when removing the second resist film 130, a fence-like residue 110b is formed as shown in FIG. 40.

When the fence-like residue 110b is formed, it is difficult to fill up the via hole 111 and the wiring trench 112 with a wiring metal, disadvantageously resulting in difficulty in formation of wires in the via hole 111 and the wiring trench 112. Even if wires 135 can be formed in the via hole 111 and the wiring trench 112, diffusion preventing films 134 and the wires 135 as formed may cause disconnection as shown in FIG. 41. Thus, the semiconductor device is disadvantageously reduced in reliability.

The problem of reduction in reliability of the semiconductor device is not restricted to the aforementioned example but is generally caused in a method of forming openings in an interlayer dielectric film in two stages through anti-reflection coatings.

### SUMMARY OF THE INVENTION

An object of the present invention is to provide a method of manufacturing a semiconductor device capable of preventing reduction of reliability when employing an anti-reflection coating for forming two stages of openings in an interlayer dielectric film.

Another object of the present invention is to simplify a manufacturing process in the aforementioned method of manufacturing a semiconductor device.

A method of manufacturing a semiconductor device according to an aspect of the present invention comprises steps of forming an anti-reflection coating on an interlayer dielectric film, forming a first resist pattern on a prescribed region of the anti-reflection coating, etching the interlayer dielectric film through a mask of the first resist pattern thereby forming a first opening in the interlayer dielectric film, removing the first resist pattern while leaving the anti-reflection coating and thereafter forming a second resist pattern on a prescribed region of the anti-reflection coating and etching the interlayer dielectric film through a mask of the second resist pattern thereby forming a second opening having a larger opening area than the first opening at least on an upper portion of the first opening.

In the method of manufacturing a semiconductor device according to this aspect, the first opening is formed in the interlayer dielectric film through the mask of the first resist pattern, thereafter the first resist pattern is removed while leaving the anti-reflection coating, and the second resist pattern is formed on the prescribed region of the anti-reflection coating for defining the second opening as hereinabove described, whereby the anti-reflection coating can be easily shared in the steps of forming the first and second openings. Thus, no additional anti-reflection coating may be formed after formation of the first opening. Therefore, the anti-reflection coating can be prevented from entering the first opening, to be inhibited from remaining therein after lithography. Consequently, reduction of reliability can be prevented when employing the anti-reflection coating for forming two stages of openings in the interlayer dielectric film. Further, the anti-reflection coating can be shared in the steps of forming the first and second openings, whereby the anti-reflection coating may be formed only once. Consequently, the manufacturing process can be simplified.

In the method of manufacturing a semiconductor device according to the aforementioned aspect, the anti-reflection coating is preferably an inorganic film. When the anti-reflection coating is made of such a material, only the first resist pattern can be easily removed while leaving the anti-reflection coating in the step of removing the first resist pattern.

In the aforementioned structure having the anti-reflection coating including an inorganic film, the anti-reflection coating may include the inorganic film of any material selected from a group consisting of SiN, polysilicon and SiON, or may contain any inorganic matter selected from a group consisting of TiN, TaN, TiO, TaO and TiSiN.

In the method of manufacturing a semiconductor device according to the aforementioned aspect, the step of removing the first resist pattern preferably includes a step of removing the first resist pattern by ashing and with a photoresist remover solution while leaving the anti-reflection coating. According to this structure, only the first resist pattern can be easily removed while leaving the anti-reflection coating in the step of removing the first resist pattern.

The method of manufacturing a semiconductor device according to the aforementioned aspect preferably further comprises steps of removing the second resist pattern after forming the second opening, filling up the first opening and the second opening with a conductive material and thereafter removing an excess depositional portion of the conductive material by polishing and removing the anti-reflection coating when removing the excess depositional portion of the conductive material by polishing. According to this structure, the anti-reflection coating can be simultaneously removed when forming the conductive material for defining a wire and a connecting portion in the first and second openings, whereby no step of separately removing the anti-reflection coating may be added. Thus, the manufacturing process can be simplified.

The method of manufacturing a semiconductor device according to the aforementioned aspect preferably further comprises steps of removing the second resist pattern after forming the second opening and thereafter removing the anti-reflection coating by etching. According to this structure, the anti-reflection coating can be easily removed after formation of the second opening.

The method of manufacturing a semiconductor device according to the aforementioned aspect preferably further comprises a step of injecting an impurity into the anti-reflection coating thereby hardening the anti-reflection coating after the step of forming the anti-reflection coating on the interlayer dielectric film in advance of the step of forming the first opening. According to this structure, only the first resist pattern can be removed while leaving the anti-reflection coating in the step of removing the first resist pattern. In this case, the anti-reflection coating may include an SOG film.

In the method of manufacturing a semiconductor device according to the aforementioned aspect, the second opening is preferably a wiring trench for a damascene wire, and the first opening is preferably a via hole for electrically connecting the damascene wire with a wiring layer located under the interlayer dielectric film. According to this structure, a wiring structure can be easily formed through a dual damascene process without reducing reliability.

In the method of manufacturing a semiconductor device according to the aforementioned aspect, the interlayer dielectric film preferably includes a film consisting of at least one material selected from a group consisting of a polymer, SiOC, MSQ, HSQ, SiOF, TEOS and SiO₂. According to this structure, line capacity can be reduced when employing a low dielectric constant insulator film consisting of a polymer, SiOC, MSQ or HSQ, for example.

In the method of manufacturing a semiconductor device according to the aforementioned aspect, the anti-reflection coating may include an anti-reflection coating consisting of TaN, and the interlayer dielectric film may include an interlayer dielectric film consisting of SiOC. Alternatively, the anti-reflection coating may include an anti-reflection coating consisting of SiON, and the interlayer dielectric film may include an interlayer dielectric film consisting of a polymer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 11 are sectional views for illustrating a process of manufacturing a semiconductor device according to a first embodiment of the present invention;

FIG. 12 is a sectional view for illustrating a process of manufacturing a semiconductor device according to a second embodiment of the present invention;

FIGS. 13 to 22 are sectional views for illustrating a process of manufacturing a semiconductor device according to a third embodiment of the present invention;

FIGS. 23 to 32 are sectional views for illustrating a process of manufacturing a semiconductor device according to a fourth embodiment of the present invention; and

FIGS. 33 to 41 are sectional views for illustrating a conventional process of manufacturing a semiconductor device.

### DESCRIPTION OF THE PREFERRED EMBODIMENTS

Embodiments of the present invention are now described with reference to the drawings.

(First Embodiment)

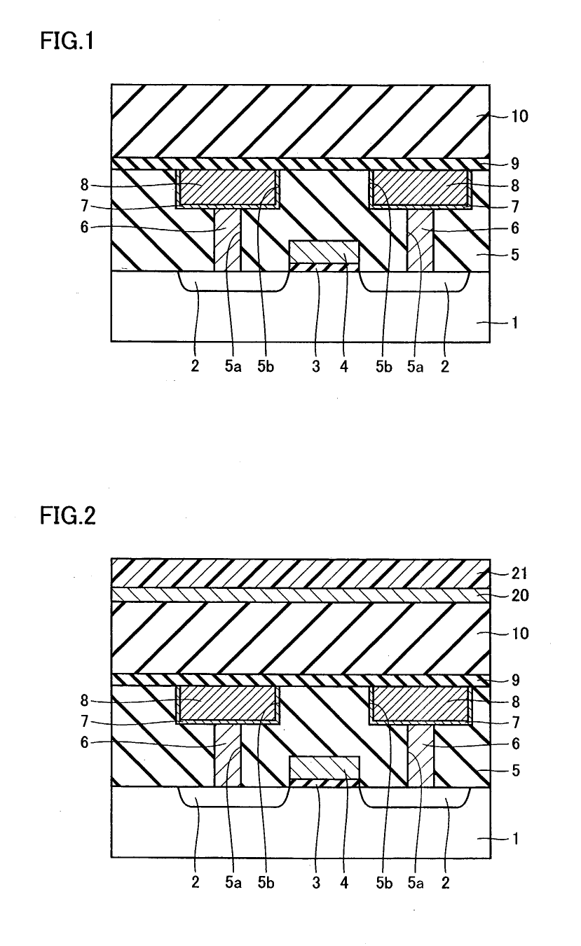

A process of manufacturing a semiconductor device according to a first embodiment of the present invention is described with reference to FIGS. 1 to 11. First, a MOS transistor and a wiring structure connected to the MOS transistor are formed on the surface of a semiconductor substrate 1, as shown in FIG. 1. The MOS transistor includes a pair of source/drain regions 2 formed at a prescribed interval to hold a channel region therebetween and a gate electrode 4 formed on the channel region through a gate insulator film 3. The wiring structure connected to the MOS transistor includes tungsten plugs 6 formed to fill up via holes 5a of an interlayer dielectric film 5, diffusion preventing films 7 of TaN formed along the surfaces of wiring trenches 5b of the interlayer dielectric film 5 and wires 8 of Cu or the like formed in regions enclosed with the diffusion preventing films 7.

The wires 8 are made of an alloy of aluminum (Al), silicon (Si) and copper (Cu), an alloy of aluminum (Al), silicon (Si) and copper (Cu) and titanium nitride (TiN) and copper (Cu) or titanium nitride (TiN) and copper (Cu).

Then, a diffusion preventing film 9 consisting of SiCN is formed to cover the overall surfaces of the aforementioned MOS transistor and the wiring structure connected to the MOS transistor. A flattened interlayer dielectric film 10 of tetraethoxysilane (TEOS) having a thickness of about 300 nm to about 1000 nm is formed by CVD to cover the diffusion preventing film 9. The diffusion preventing films 7 and 9 are provided for preventing copper (Cu) contained in the wires 8 from diffusing into the interlayer dielectric films 5 and 10.

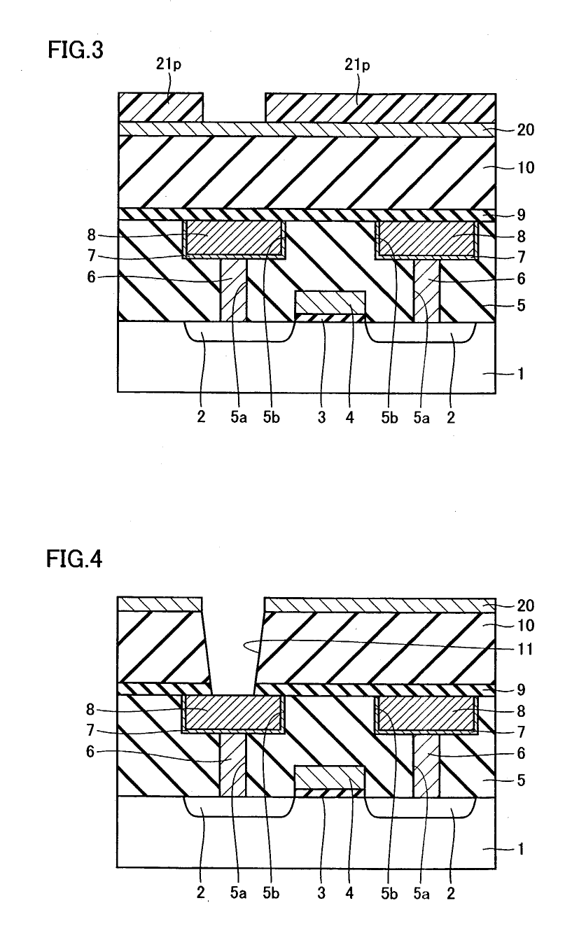

Then, an anti-reflection coating 20 consisting of inorganic matter such as a nitride containing a transition metal element such as TiN, TaN or TiSiN or an oxide containing a transition metal element such as TiO or TaO is formed with a thickness of about 3 nm to about 30 nm, as shown in FIG. 2. A first resist film 21 based on Novolac resin is applied onto the anti-reflection coating 20 with a thickness of about 200 nm to about 1000 nm. A resist pattern 21p for defining a via hole 11 is formed as shown in FIG. 3 through treatments such as exposure, development, rinsing and baking on the first resist film 21. The resist pattern 21p is an example of the “first resist pattern” in the present invention.

As shown in FIG. 4, the resist pattern 21p is employed as a mask for anisotropically etching the anti-reflection coating 20. The anti-reflection coating 20 is anisotropically etched under the following conditions:

Ar Flow Rate: about 150 sccm

CH₄ Flow Rate: about 6 sccm

Cl₂ Flow Rate: about 100 sccm

BCl₃ Flow Rate: about 25 sccm

Pressure: about 2 Pa

Microwave Power: about 800 W

RF Power: about 30 W

Further, the interlayer dielectric film 10 and the diffusion preventing film 9 are anisotropically etched thereby forming the via hole 11 in the interlayer dielectric film 10 and the diffusion preventing film 9. The via hole 11 is an example of the “first opening” in the present invention. The interlayer dielectric film 10 and the diffusion preventing film 9 are anisotropically etched by setting the reaction chamber employed for etching the anti-reflection coating 20 to a pressure of about 0.1 Pa to about 2.0 Pa and employing C₄F₈—, Ar— or O₂-based gas. At this time, CO, CHF₃, N₂ or CH₂F₂ may be employed as additive gas.

After forming the via hole 11 in the aforementioned manner, only the resist pattern 21p based on organic Novolac resin is removed while leaving the anti-reflection coating 20 consisting of a conductor. More specifically, the reaction chamber is set to a pressure of about 10 Pa to about 100 Pa with O₂ gas, a gas mixture of H₂ and N₂, NH₃ gas or H₂O and ashing is performed in plasma excited at a high frequency for 0 to about 100 seconds. Thereafter the resist pattern 21p is dipped in an organic amine release cleaning solution heated to about 15° C. to about 100° C. for about 5 seconds to about 600 seconds, thereby removing only the resist pattern 21p while leaving the anti-reflection coating 20.

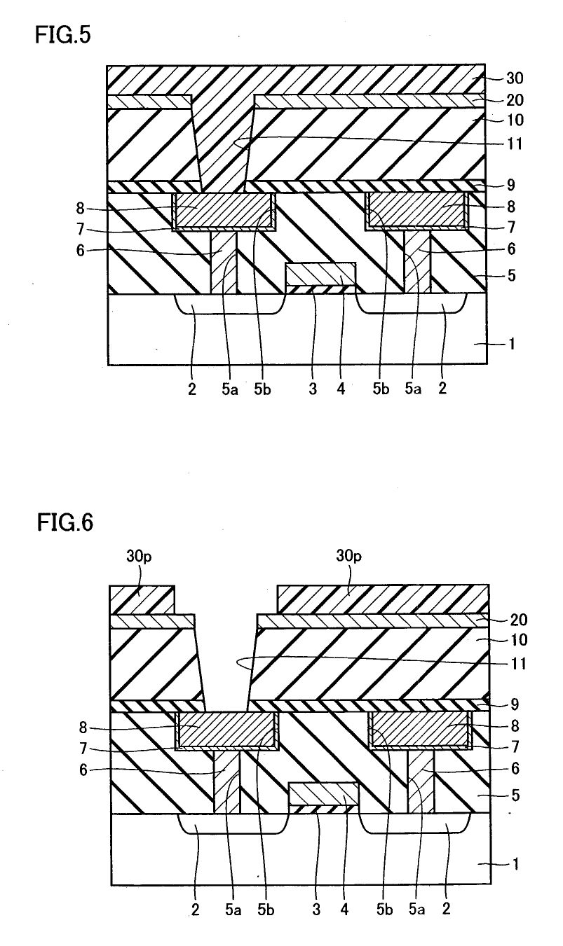

As shown in FIG. 5, a second resist film 30 based on Novolac resin is applied with a thickness of about 200 nm to about 1000 nm. Then, a resist pattern 30p for defining a wiring trench (damascene wire) 12 is formed as shown in FIG. 6 through treatments such as exposure, development, rinsing and baking on the second resist film 30. The resist pattern 30p is an example of the “second resist pattern” in the present invention.

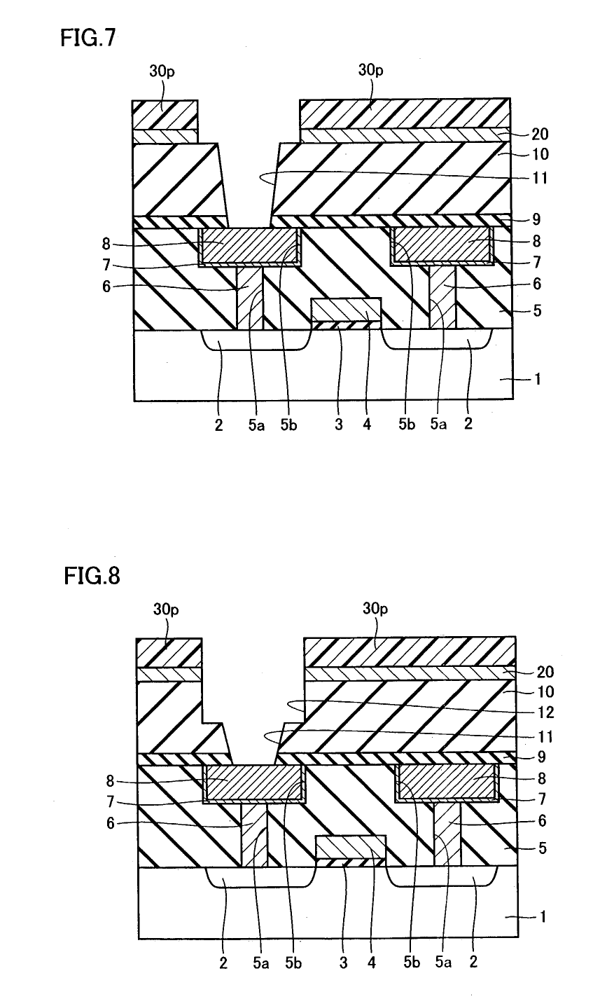

As shown in FIG. 7, the anti-reflection coating 20 consisting of inorganic matter such as a nitride containing a transition metal element such as TiN, TaN or TiSiN or an oxide containing a transition metal element such as TiO or TaO is anisotropically etched through a mask of the resist pattern 30p. The anti-reflection coating 20 is anisotropically etched under the same conditions as those in the aforementioned anisotropic etching for the anti-reflection coating 20 through the mask of the resist pattern 21p.

As shown in FIG. 8, the wiring trench 12 is formed in the interlayer dielectric film 10 by anisotropic etching. The wiring trench 12 is an example of the “second opening” in the present invention. The interlayer dielectric film 10 is anisotropically etched by setting the reaction chamber to a pressure of about 0.1 Pa to about 2.0 Pa and employing C₄F₈— Ar— or O₂-based gas. At this time, CO, CHF₃, N₂, CH₂F₂ or CF₄ may be employed as additive gas.

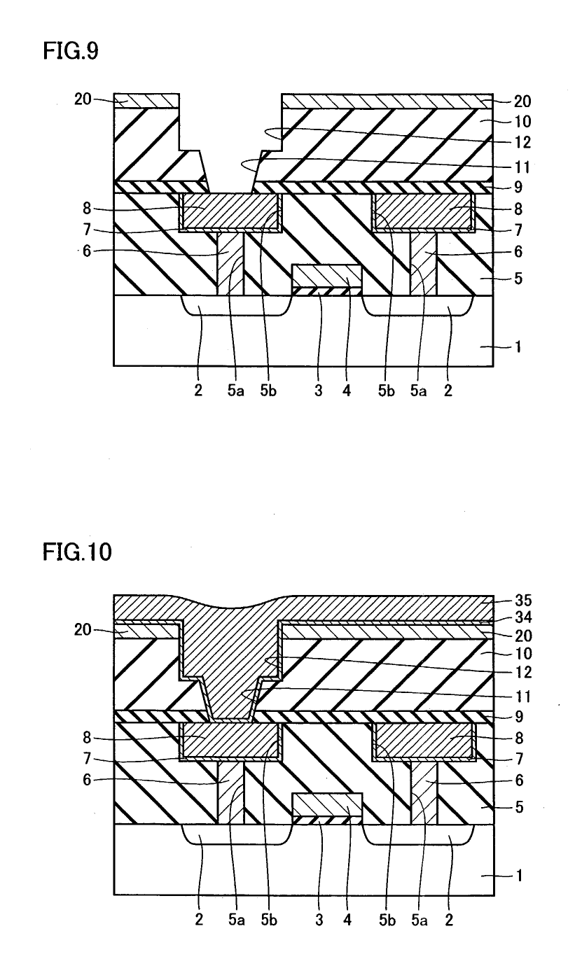

Then, the resist pattern 30p is removed thereby obtaining a shape shown in FIG. 9. The resist pattern 30p is removed by setting the aforementioned reaction chamber to a pressure of about 10 Pa to about 100 Pa with O₂ gas, a gas mixture of H₂ and N₂, NH₃ gas or H₂O while performing ashing in plasma excited at a high frequency for about 10 seconds to about 150 seconds and thereafter dipping the resist pattern 30p in an organic amine release cleaning solution heated to about 15° C. to about 100° C. for about 5 seconds to about 600 seconds.

As shown in FIG. 10, a diffusion preventing film 34 of TaN having a thickness of about 3 nm to about 30 nm is formed to cover the via hole 11, the wiring trench 12 and the anti-reflection coating 20, and a wiring metal film 35 of Cu or the like is thereafter formed to fill up the via hole 11 and the wiring trench 12. The diffusion preventing film 34 is provided for preventing copper (Cu) contained in the wiring metal film 35 from diffusing into the interlayer dielectric film 10. Thereafter excess depositional portions of the wiring metal film 35 and the diffusion preventing film 34 are removed by CMP. At this time, the anti-reflection coating 20 consisting of inorganic matter is also removed. Thus, a wiring structure according to the first embodiment can be obtained through a dual damascene process as shown in FIG. 11.

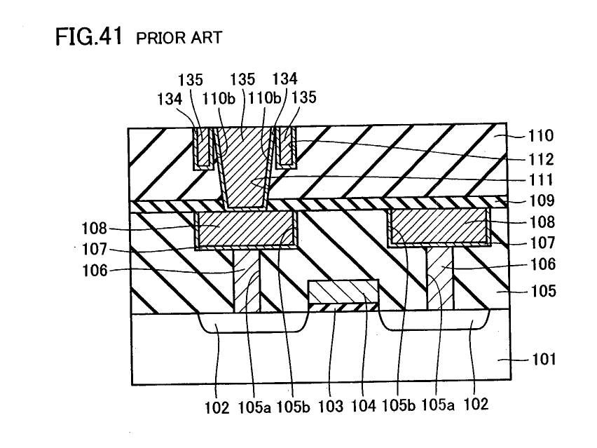

According to the first embodiment, the first resist film 21 is removed after the step of forming the via hole 11 and the second resist film 30 is formed on the anti-reflection coating 20 employed for forming the via hole 11 as hereinabove described, whereby no additional anti-reflection coating may be formed after formation of the via hole 11. Therefore, the anti-reflection coating 20 can be prevented from entering the via hole 11, to be inhibited from remaining therein after lithography. Consequently, the via hole 11 and the wiring trench 12 can be formed in the interlayer dielectric film 10 without forming the fence-like residue 110b resulting in the prior art as shown in FIG. 41, whereby the wire (the wiring metal film 35) can be prevented from reduction of reliability.

According to the first embodiment, the anti-reflection coating 21 can be shared in the steps of forming the via hole 11 and the wiring trench 12, whereby the anti-reflection coating 20 may be formed only once. Consequently, the manufacturing process can be simplified.

According to the first embodiment, further, the anti-reflection coating 20 consisting of inorganic matter is also removed when removing the excess depositional portions of the wiring metal film 35 and the diffusion preventing film 34 by CMP after forming the wiring metal film 35 of Cu or the like to fill up the via hole 11 and the wiring trench 12 as hereinabove described, whereby no additional step may be required for separately removing the anti-reflection coating 20. Thus, the manufacturing process can be simplified.

(Second Embodiment)

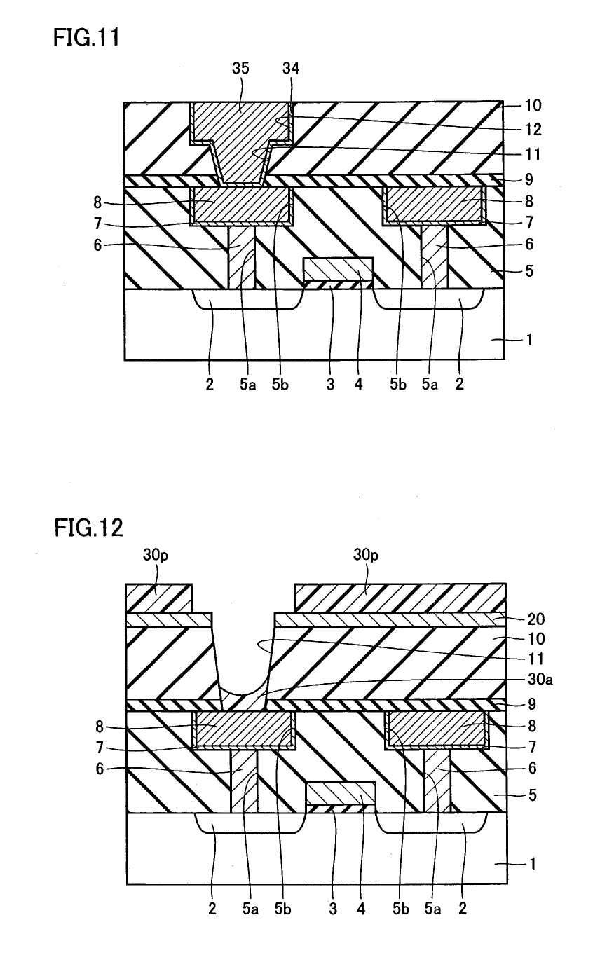

Referring to FIG. 12, a process of manufacturing a semiconductor device according to a second embodiment of the present invention is described with reference to a residue 30a of a second resist film 30 remaining in a via hole 11.

In a step of forming a resist pattern 30p consisting of the second resist film 30 similar to that in the first embodiment shown in FIGS. 5 and 6, the residue 30a of the second resist film 30 may remain in the via hole 11 as shown in FIG. 12.

According to the second embodiment, therefore, a step of removing the residue 30a by anisotropic etching is provided after a step of patterning the second resist film 30 by lithography similar to that shown in FIG. 6 and in advance of a step of etching an anti-reflection coating 20 similar to that shown in FIG. 7. This anisotropic etching is performed in an ECR (electron cyclotron resonance) etcher for about 10 seconds under the following conditions:

O₂ Flow Rate: about 10 cm

Pressure: about 0.266 Pa

Microwave Power: about 1500 W

RF Power: about 20 W

According to the second embodiment, the residue 30a of the second resist film 30 entering the via hole 11 is removed by anisotropic etching in advance of the step of etching the anti-reflection coating 20 as hereinabove described, whereby the anti-reflection coating 20 can be etched and etching for forming a wiring trench 12 can be performed with no residue 30a remaining in the via hole 11. Thus, the wiring trench 12 can be prevented from defective formation or the like resulting from the residue 30a.

(Third Embodiment)

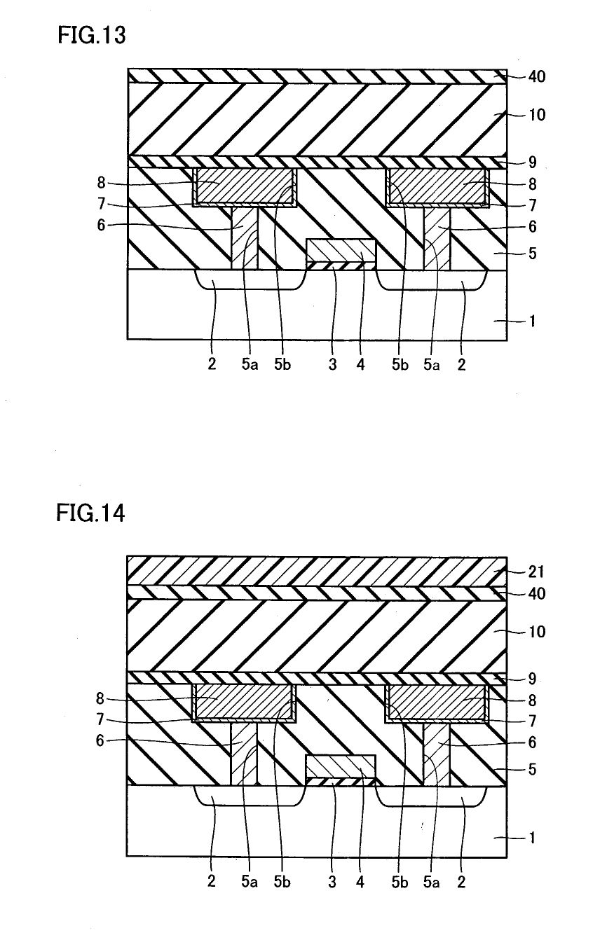

Referring to FIGS. 13 to 22, a method of manufacturing a semiconductor device according to a third embodiment of the present invention is described with reference to a case of employing an anti-reflection coating 40 consisting of a polysilicon film, which is an inorganic film, dissimilarly to the aforementioned first embodiment.

First, elements up to wires 8 are formed through a manufacturing process similar to that according to the first embodiment, as shown in FIG. 13. A diffusion preventing film 9 consisting of SiCN is formed to cover the overall surface. Then, an interlayer dielectric film 10 is formed to cover the diffusion preventing film 9. Thereafter the anti-reflection coating 40 consisting of polysilicon is formed on the interlayer dielectric film 10 with a thickness of about 30 nm to about 150 nm.

As shown in FIG. 14, a first resist film, 21 based on Novolac resin is applied with a thickness of about 200 nm to about 1000 nm. A resist pattern 21p for defining a via hole 11 is formed as shown in FIG. 15 through treatments such as exposure, development, rinsing and baking on the first resist film 21.

As shown in FIG. 15, the resist pattern 21p is employed as a mask for anisotropically etching the anti-reflection coating 40. This anisotropic etching is performed in an ECR (electron cyclotron resonance) etcher for about 15 seconds under the following conditions:

Cl₂ Flow Rate: about 10 cm

O₂ Flow Rate: about 4 sccm

Pressure: about 0.266 Pa

Microwave Power: about 1500 W

RF Power: about 40 W

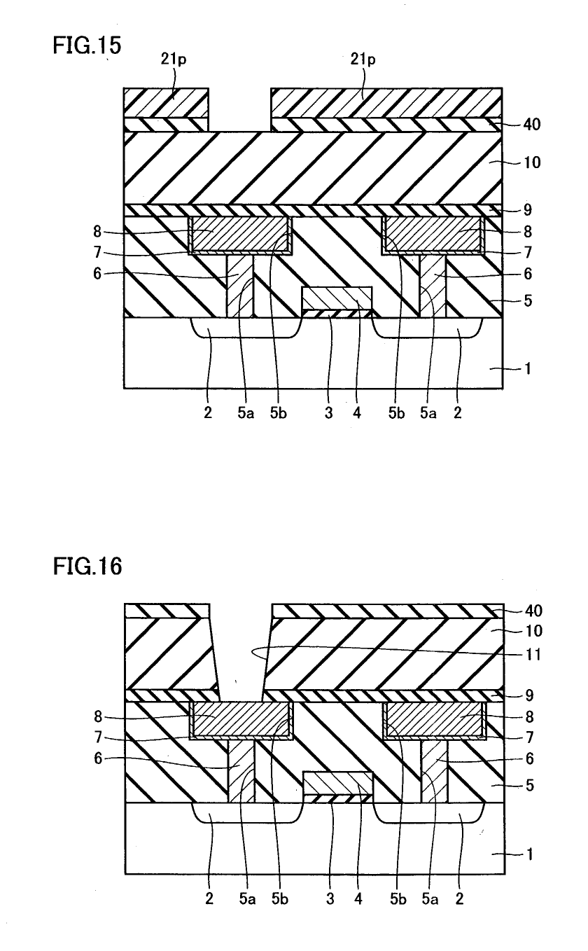

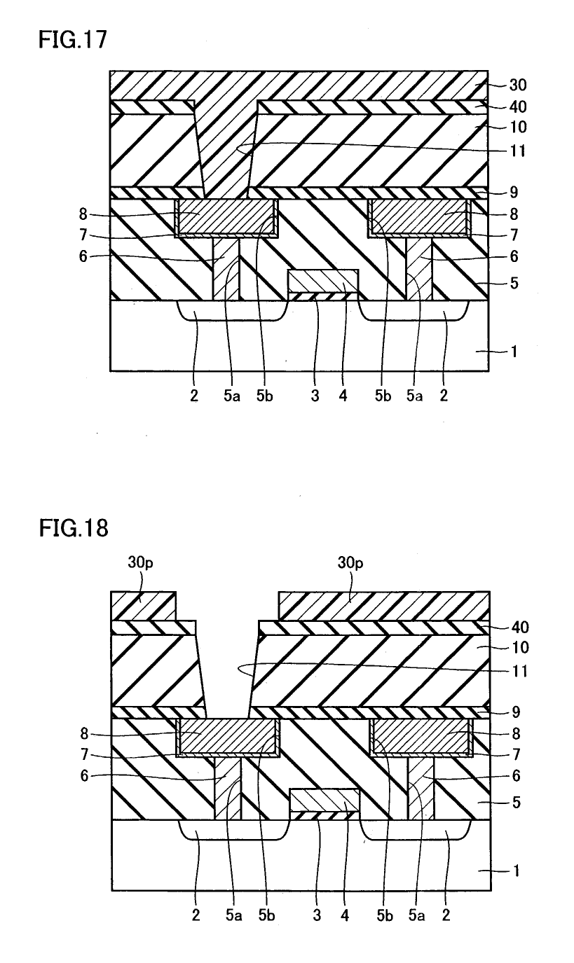

As shown in FIG. 16, the via hole 11 is formed in the interlayer dielectric film 10 and the diffusion preventing film 9 by anisotropic etching, and only the resist pattern 21p is thereafter removed while leaving the anti-reflection coating 40. As shown in FIG. 17, a second resist film 30 based on Novolac resin is applied with a thickness of about 200 nm to about 1000 nm. A resist pattern 30p for defining a wiring trench (damascene wire) 12 is formed as shown in FIG. 18 through treatments such as exposure, development, rinsing and baking on the second resist film 30.

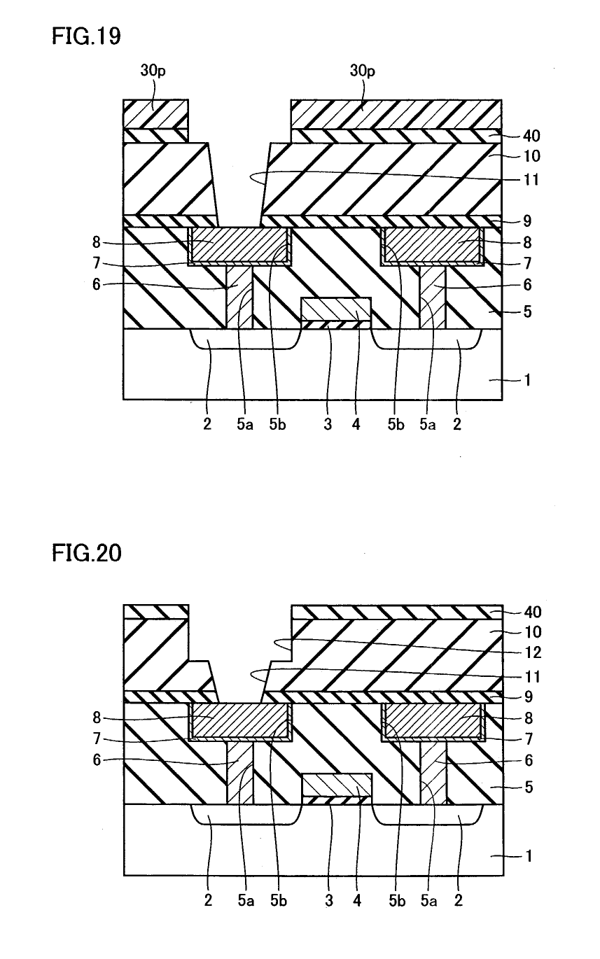

As shown in FIG. 19, the resist pattern 30p is employed as a mask for anisotropically etching the anti-reflection coating 40. The anti-reflection coating 40 is anisotropically etched under the same conditions as those employed in the step of etching the anti-reflection coating 40 shown in FIG. 15.

The resist pattern 30p and the anti-reflection coating 40 are employed as masks for forming the wiring trench 12 in the interlayer dielectric film 10 by anisotropic etching, and the resist pattern 30p is thereafter removed. The resist pattern 30p is removed by setting a reaction chamber to a pressure of about 10 Pa to about 100 Pa with O₂ gas, a gas mixture of H₂ and N₂, NH₃ gas or H₂O while performing ashing in plasma excited at a high frequency for 0 to 10 seconds and thereafter dipping the resist pattern 30p in an organic amine release cleaning solution heated to about 15° C. to about 100° C. for about 5 seconds to about 600 seconds. Thus, a shape shown in FIG. 20 is obtained.

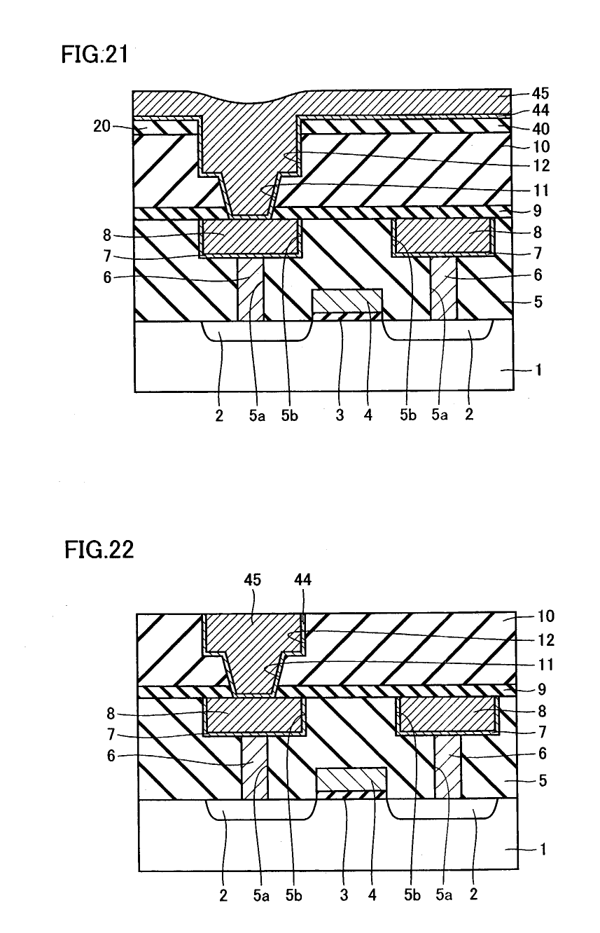

As shown in FIG. 21, a diffusion preventing film 44 of TaN having a thickness of about 3 nm to about 30 nm is formed to cover the via hole 11 and the wiring trench 12 as well as the anti-reflection coating 20, and a wiring metal film 45 of Cu or the like is thereafter formed to fill up the via hole 11 and the wiring trench 12. Thereafter excess depositional portions of the wiring metal film 45 and the diffusion preventing film 44 are removed by CMP. At this time, the anti-reflection coating 40 consisting of inorganic matter (polysilicon) is also removed. Thus, a wiring structure according to the third embodiment can be obtained through a dual damascene process as shown in FIG. 22.

According to the third embodiment, the anti-reflection coating 40 consisting of polysilicon which is inorganic matter is so employed as hereinabove described that only the resist-pattern 21p can be easily removed while leaving the anti-reflection coating 40 in the step of removing the resist pattern 21p.

(Fourth Embodiment)

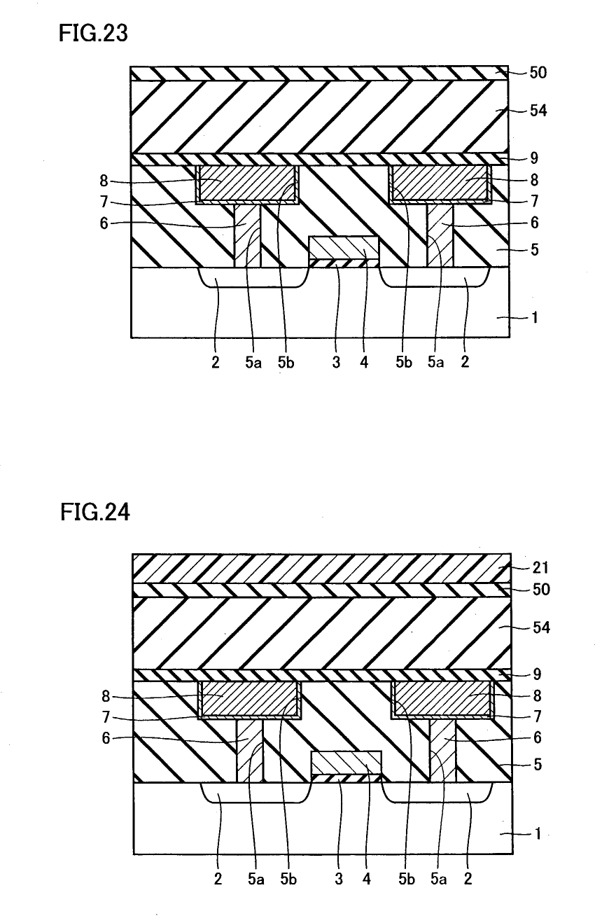

Referring to FIGS. 23 to 32, a method of manufacturing a semiconductor device according to a fourth embodiment of the present invention is described with reference to a case of employing an anti-reflection coating 50 consisting of TaN and an interlayer dielectric film 54 consisting of SiOC, dissimilarly to the aforementioned third embodiment.

First, elements up to wires 8 are formed through a manufacturing process similar to that according to the first embodiment, as shown in FIG. 23. A diffusion preventing film 9 consisting of SiCN is formed to cover the overall surface. Then, the interlayer dielectric film 54 consisting of SiOC is formed to cover the diffusion preventing film 9. Thereafter the anti-reflection coating 50 consisting of TaN is formed on the interlayer dielectric film 54 with a thickness of about 10 nm to about 150 nm.

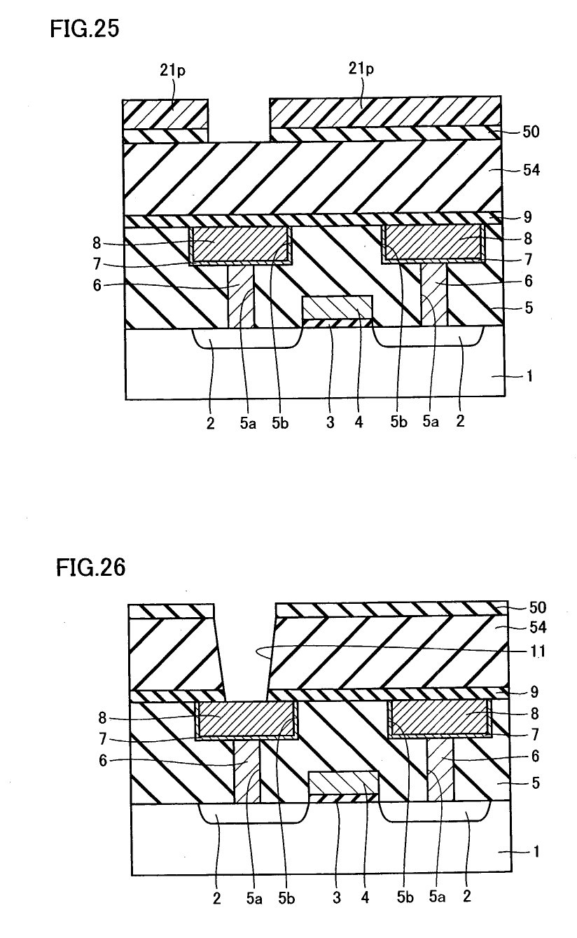

As shown in FIG. 24, a first resist film 21 based on Novolac resin is applied with a thickness of about 200 nm to about 1000 nm. A resist pattern 21p for defining, a via hole 11 is formed as shown in FIG. 25 through treatments such as exposure, development, rinsing and baking on the first resist film 21.

As shown in FIG. 25, the resist pattern 21p is employed as a mask for anisotropically etching the anti-reflection coating 50. This anisotropic etching is. performed in an ECR (electron cyclotron resonance) etcher for about 60 seconds under the following conditions:

Ar Flow Rate: about 150 sccm

CH₄ Flow Rate: about 6 sccm

Cl₂ Flow Rate: about 100 sccm

BCl₃ Flow Rate: about 25 sccm

Pressure: about 2 Pa

Microwave Power: about 800 W

RF Power: about 30 W

As shown in FIG. 26, the via hole 11 is formed in the interlayer dielectric film 54 consisting of SiOC and the diffusion preventing film 9 consisting of SiCN by anisotropic etching, and only the resist pattern 21p is thereafter removed while leaving the anti-reflection coating 50. This anisotropic etching is performed in an MERIE (magnetron RIE) etcher under the following conditions:

Ar Flow rate: about 500 sccm

N₂ Flow Rate: about 90 sccm

CF₄ Flow Rate: about 30 sccm

CH₂H₂ Flow Rate: about 10 cm

Pressure: about 6 Pa

RF Power: about 1000 W

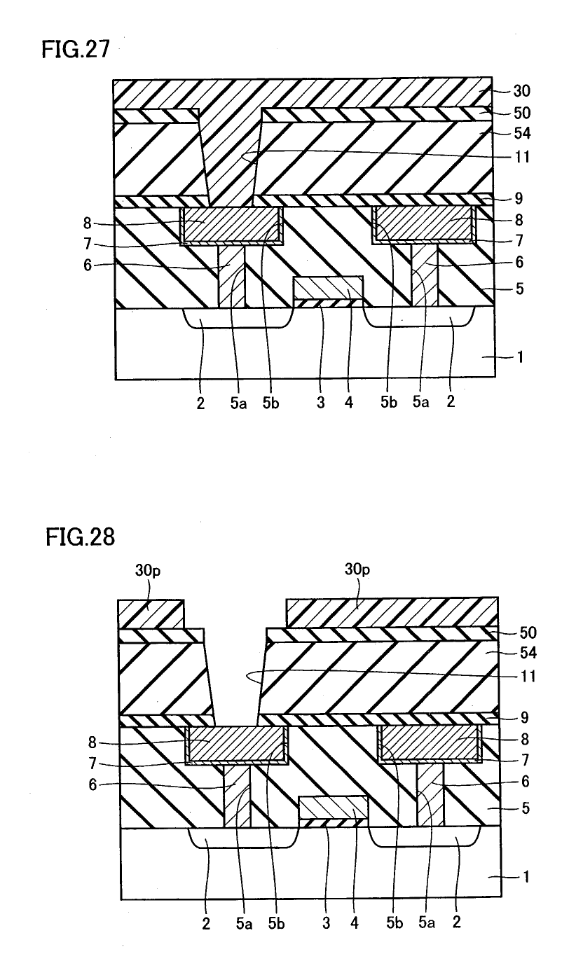

As shown in FIG. 27, a second resist film 30 based on Novolac resin is applied with a thickness of about 200 nm to about 1000 nm. A resist pattern 30p for defining a wiring trench (damascene wire) 12 is formed as shown in FIG. 28 through treatments such as exposure, development, rinsing and baking on the second resist film 30.

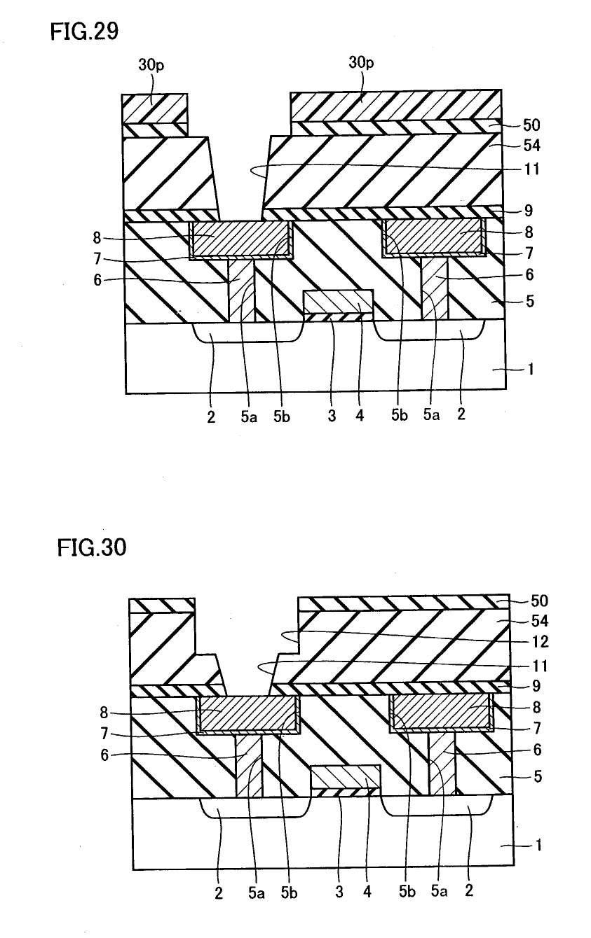

As shown in FIG. 29, the resist pattern 30p is employed as a mask for anisotropically etching the anti-reflection coating 50. The anti-reflection coating 50 is anisotropically etched under the same conditions as those employed in the step of etching the anti-reflection coating 50 shown in FIG. 25.

The resist pattern 30p and the anti-reflection coating 50 are employed as masks for forming the wiring trench 12 in the interlayer dielectric film 54 by anisotropic etching, and the resist pattern 30p is thereafter removed. The resist pattern 30p is removed by setting a reaction chamber to a pressure of about 10 Pa to about 100 Pa with O₂ gas, a gas mixture of H₂ and N₂, NH₃ gas or H₂O while performing ashing in plasma excited at a high frequency for 0 to 10 seconds and thereafter dipping the resist pattern 30p in an organic amine release cleaning solution heated to about 15° C. to about 100° C. for about 5 seconds to about 600 seconds. Thus, a shape shown in FIG. 30 is obtained.

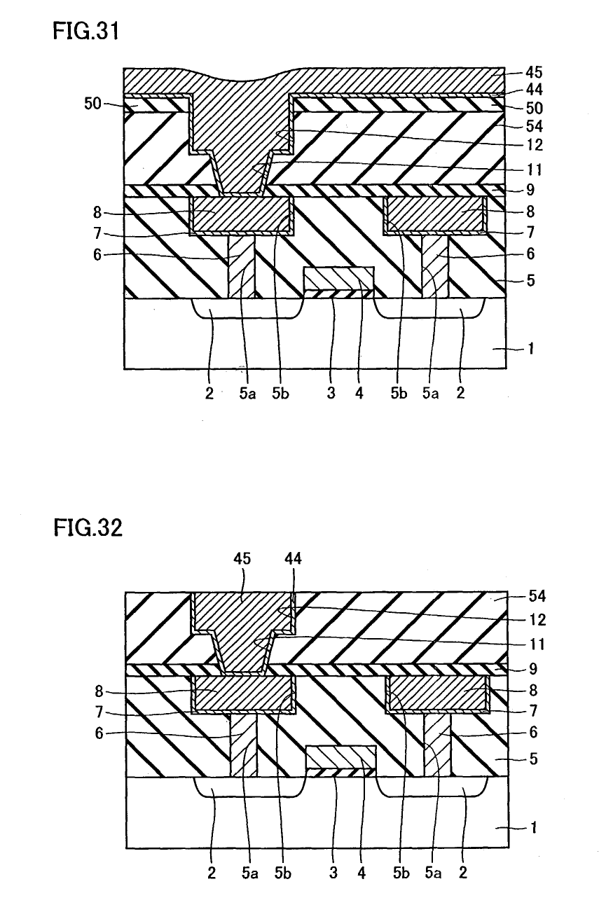

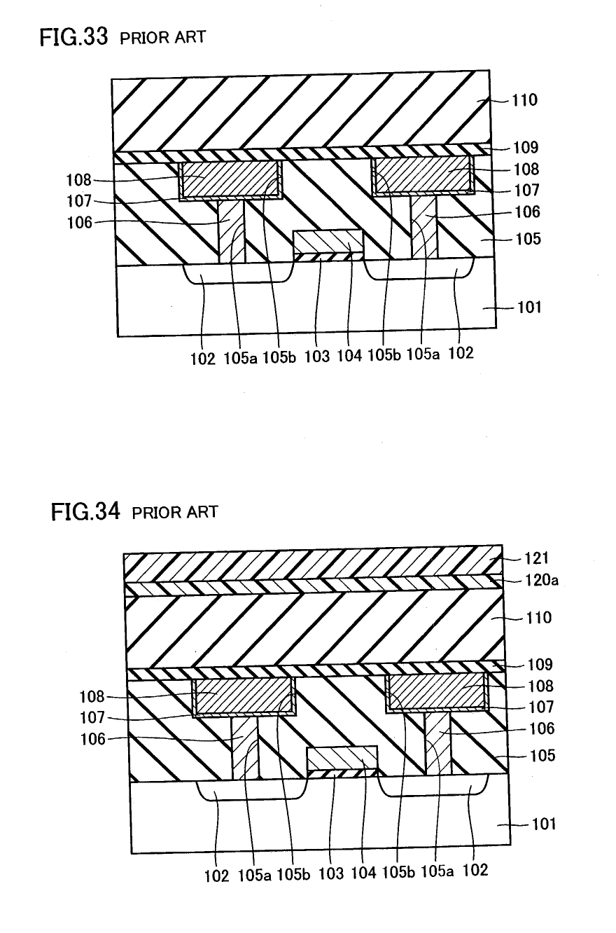

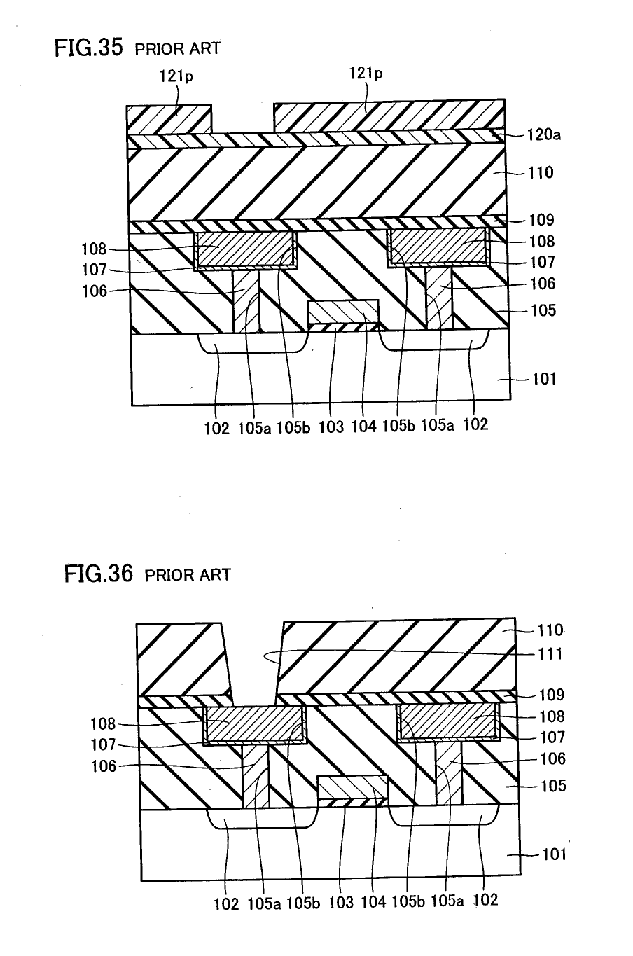

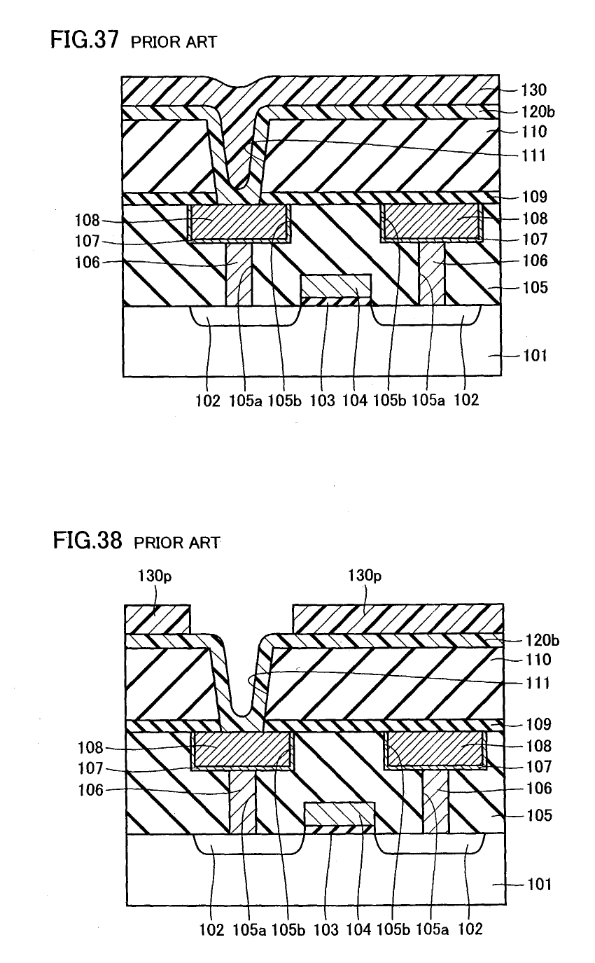

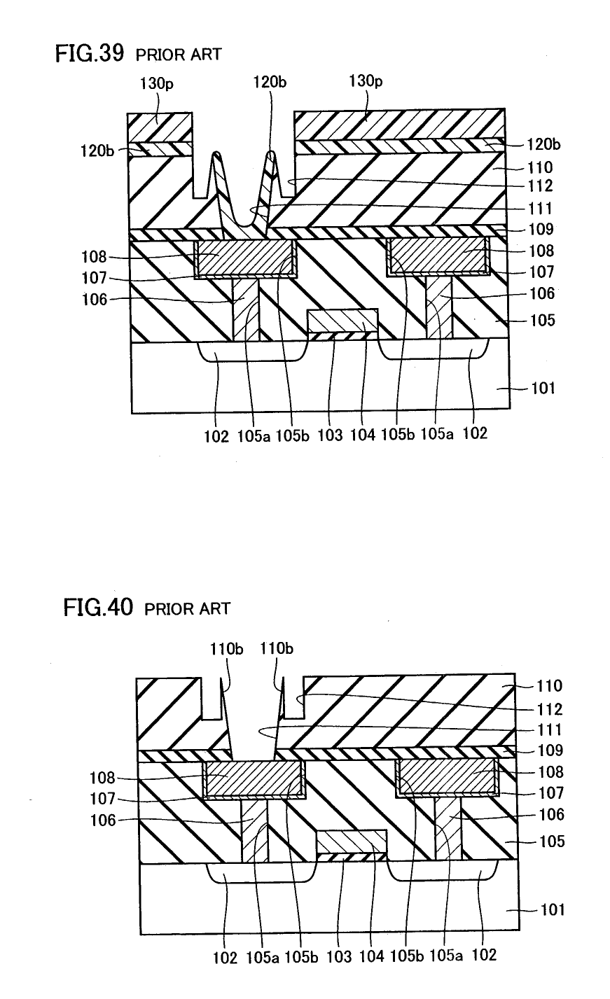

As shown in FIG. 31, a diffusion preventing film 44 of TaN having a thickness of about 3 nm to about 30 nm is formed to cover the via hole 11 and the wiring trench 12 as well as the anti-reflection coating 50, and a wiring metal film 45 of Cu or the like is thereafter formed to fill up the via hole 11 and the wiring trench 12. Thereafter excess depositional portions of the wiring metal film 45 and the diffusion preventing film 44 are removed by CMP. At this time, the anti-reflection coating 50 consisting of inorganic matter (TaN) is also removed. Thus, a wiring structure according to the fourth embodiment can be obtained through a dual damascene process as shown in FIG. 32.

According to the fourth embodiment, the anti-reflection coating 50 consisting of TaN is so employed as hereinabove described that only the resist pattern 21p can be easily removed while leaving the anti-reflection coating 50 in the step of removing the resist pattern 21p.

Alternatively, a diffusion preventing film consisting of SiN and an interlayer dielectric film consisting of a polymer may be employed in place of the diffusion preventing film 9 consisting of SiCN and the interlayer dielectric film 54 consisting of SiOC respectively as a modification of the fourth embodiment employing the anti-reflection coating 50 consisting of TaN. In this case, the interlayer dielectric film consisting of a polymer is anisotropically etched in the step of forming the via hole 11 in an MERIE (magnetron RIE) etcher under the following conditions:

NH₃ Flow Rate: about 100 sccm

Pressure: about 6 Pa

RF Power: about 1000 W

The diffusion preventing film consisting of SiN is anisotropically etched under the same conditions for the diffusion preventing film 9 consisting of SiCN shown in FIG. 26.

Although the present invention has been described and illustrated in detail, it is clearly understood that the same is by way of illustration and example only and is not to be taken by way of limitation, the spirit and scope of the present invention being limited only by the terms of the appended claims.

For example, the anti-reflection coating 20, 40 or 50 may alternatively be made of another material such as an insulator, a conductor or a semiconductor other than that illustrated in each of the aforementioned embodiments.

More specifically, while the inorganic anti-reflection coating 40 consisting of polysilicon is employed in the aforementioned third embodiment, the present invention is not restricted to this but the anti-reflection coating 40 may alternatively consist of another inorganic matter such as SiN or SiON.

While the anti-reflection coating 50 consists of TaN in the fourth embodiment and the modification thereof, the present invention is not restricted to this but a similar effect can be attained also when the anti-reflection coating 50 consists of TiN, TiO, TaO, TiSiN or a multilayer of films consisting of these materials.

The anti-reflection coating 20, 40 or 50 may contain at least a semimetal element such as carbon, silicon or germanium. Further, the anti-reflection coating 20, 40 or 50 may contain at least nitrogen, or at least hydrogen. In addition, the anti-reflection coating 20, 40 or 50 may contain at least all of carbon, silicon, oxygen, nitrogen and hydrogen. Further, the anti-reflection coating 20, 40 or 50 may be formed by stacking a plurality of films consisting of such materials. A film of a transition metal such as Cr, W or Ni may be formed on the anti-reflection coating 20, 40 or 50.

While the anti-reflection coating 20, 40 or 50 is removed when forming the wire by CMP in each of the aforementioned embodiments, the present invention is not restricted to this but the anti-reflection coating 20, 40 or 50 may alternatively be removed by dry etching. When made of silicon nitride (SiN), the anti-reflection coating 20, 40 or 50 may be removed by wet etching with hot phosphoric acid.

While the interlayer dielectric film 5, 10 or 54 is formed by a TEOS film, an SiOC film or a polymer film in each of the aforementioned embodiments and the modification of the fourth embodiment, the present invention is not restricted to this but an interlayer dielectric film consisting of a low dielectric constant film of methylsilsesquisiloxane (MSQ), hydrogenated silsesquioxane polymer (HSQ) or SiOF or SiO₂ or a multilayer of films consisting of these materials may alternatively be employed.

An impurity such as ions may be implanted into the anti-reflection coating 20, 40 or 50 after forming the anti-reflection coating 20, 40 or 50 and before forming the first resist film 21 in each of the aforementioned embodiments. Thus, the anti-reflection coating 20, 40 or 50 can be hardened. Therefore, the anti-reflection coating 20, 40 or 50 employed for patterning the first resist film 21 can be easily reused for patterning the second resist film 30.

In this case, the anti-reflection coating 20, 40 or 50 is preferably prepared by implanting ions into an organic SOG film. More specifically, ion implantation is employed for implanting boron ions (B+) into the organic SOG film under conditions of acceleration energy of about 80 keV and a dose of about 2×10¹⁵ ions/cm². Thus, the portion of the organic SOG film containing the implanted boron ions is modified to a densified modified SOG film containing no organic component and only slight quantities of moisture and hydroxyl groups. Consequently, an anti-reflection coating consisting of a hardened modified SOG film is obtained.

While the diffusion preventing film 9, 20 or 34 is anisotropically etched after anisotropically etching the interlayer dielectric film 5, 10 or 54 in the etching step for forming the via hole 11 in each of the aforementioned embodiments, the present invention is not restricted to this but anisotropic etching performed on the interlayer dielectric film 5, 10 or 54 in the etching step for forming the via hole 11 may alternatively be stopped in the diffusion preventing film 9, 20 or 34, not to reach the lower wiring layer. The remaining part of the diffusion preventing film 9, 20 or 34 is removed by etching (etching back) the overall surface of the substrate 1 after etching the wiring trench 12 and performing ashing. Thus, damage on the surface of the Cu wire 8 resulting from over-etching of the via hole 11 and the wiring trench 12 can be reduced and the stage of Cu exposure in an etching chamber can be retarded, thereby inhibiting the chamber from Cu contamination.

While the present invention is applied to the case of forming the wiring trench 12 for the damascene wire and the via hole 11 in the interlayer dielectric film 10 or 54 in each of the aforementioned embodiments, the present invention is not restricted to this but is widely applicable to a case of forming a first opening in an interlayer dielectric film by lithography and thereafter enlarging at least an upper portion of the first opening into a second opening having a larger opening area than the first opening.

While the via hole 11 is formed as the first opening and the wiring trench 12 is formed as the second opening in each of the aforementioned embodiments, the present invention is not restricted to this but is also applicable to first and second openings both formed by wiring trenches.

What is claimed is:

1. A method of manufacturing a semiconductor device comprising steps of:
forming an anti-reflection coating on an interlayer dielectric film;
forming a first resist pattern on a prescribed region of said anti-reflection coating;
etching said interlayer dielectric film through a mask of said first resist pattern thereby forming a first opening in said interlayer dielectric film;
removing said first resist pattern while leaving said anti-reflection coating and thereafter forming a second resist pattern on a prescribed region of said anti-reflection coating; and
etching said interlayer dielectric film through a mask of said second resist pattern thereby forming a second opening having a larger opening area than said first opening at least on an upper portion of said first opening.

2. The method of manufacturing a semiconductor device according to claim 1, wherein
said anti-reflection coating includes an inorganic film.

3. The method of manufacturing a semiconductor device according to claim 2, wherein
said anti-reflection coating includes said inorganic film of any material selected from a group consisting of SiN, polysilicon and SiON.

4. The method of manufacturing a semiconductor device according to claim 2, wherein
said anti-reflection coating contains any inorganic matter selected from a group consisting of TiN, TaN, TiO, TaO and TiSiN.

5. The method of manufacturing a semiconductor device according to claim 1, wherein
said step of removing said first resist pattern includes a step of removing said first resist pattern by ashing and with a photoresist remover solution while leaving said anti-reflection coating.

6. The method of manufacturing a semiconductor device according to claim 1, further comprising steps of:
removing said second resist pattern after forming said second opening,
filling up said first opening and said second opening with a conductive material and thereafter removing an excess depositional portion of said conductive material by polishing, and
removing said anti-reflection coating when removing said excess depositional portion of said conductive material by polishing.

7. The method of manufacturing a semiconductor device according to claim 1, further comprising steps of:
removing said second resist pattern after forming said second opening, and
thereafter removing said anti-reflection coating by etching.

8. The method of manufacturing a semiconductor device according to claim 1, further comprising a step of injecting an impurity into said anti-reflection coating thereby hardening said anti-reflection coating after said step of forming said anti-reflection coating on said interlayer dielectric film in advance of said step of forming said first opening.

9. The method of manufacturing a semiconductor device according to claim 8, wherein
said anti-reflection coating includes an SOG film.

10. The method of manufacturing a semiconductor device according to claim 1, wherein
said second opening is a wiring trench for a damascene wire, and
said first opening is a via hole for electrically connecting said damascene wire with a wiring layer located under said interlayer dielectric film.

11. The method of manufacturing a semiconductor device according to claim 1, wherein
said interlayer dielectric film includes a film consisting of at least one material selected from a group consisting of a polymer, SiOC, MSQ, HSQ, SiOF, TEOS and SiO₂.

12. The method of manufacturing a semiconductor device according to claim 1, wherein
said anti-reflection coating includes an anti-reflection coating consisting of TaN, and
said interlayer dielectric film includes an interlayer dielectric film consisting of SiOC.

13. The method of manufacturing a semiconductor device according to claim 1, wherein
said anti-reflection coating includes an anti-reflection coating consisting of SiON, and
said interlayer dielectric film includes an interlayer dielectric film consisting of a polymer.
